(19) United States
(12) Patent Application Publication
(10) Pub. No.: US 2018/0301576 A1
(43) Pub. Date: Oct. 18, 2018

(54) COMPOUND SEMICONDUCTOR SOLAR CELL AND METHOD FOR MANUFACTURING THE SAME

(71) Applicant: LG ELECTRONICS INC., Seoul (KR)

(72) Inventors: Jinhee PARK, SEOUL (KR); Soohyun KIM, SEOUL (KR)

(73) Assignee: LG ELECTRONICS INC., SEOUL (KR)

(21) Appl. No.: 15/949,679

(22) Filed: Apr. 10, 2018

(30) Foreign Application Priority Data
Apr. 12, 2017 (KR) 10-2017-0047306

(51) Int. Cl. H01L 31/0224; H01L 31/056; H01L 31/18

(52) U.S. Cl. CPC H01L 31/022433; H01L 31/1844; H01L 31/056

(57) ABSTRACT

A method for manufacturing a compound solar cell includes forming a rear electrode including a first electrode layer directly contacting a rear surface of a compound semiconductor layer and a second electrode layer positioned on a rear surface of the first electrode layer and formed of a material different from the first electrode layer, and forming a plurality of front electrodes on a front surface of the compound semiconductor layer, forming a plurality of first etch stop layers covering the plurality of front electrodes, and a second etch stop layer covering the front edge portions and the side surfaces of the compound semiconductor layers, etching a portion of the compound semiconductor layer not covered by the plurality of first etch stop layer from the front surface to the rear surface of the compound semiconductor layer, and scribing the rear electrode at a portion where the compound semiconductor layer is removed.

### CROSS-REFERENCE TO RELATED APPLICATION

This application claims priority to and the benefit of Korean Patent Application No. 10-2017-0047306 filed in the Korean Intellectual Property Office on Apr. 12, 2017, the entire contents of which are incorporated herein by reference.

### BACKGROUND OF THE INVENTION

### (a) Field of the Invention

The disclosure is related to a compound solar cell and manufacturing therefor to reduce cost and improve the yield by securing stability in the mesa etching process

### (b) Description of the Related Art

A compound semiconductor is not made of a single element such as silicon (Si) and germanium (Ge), but rather, is formed by a combination of two or more kinds of elements to operate as a semiconductor. Various kinds of compound semiconductors have been currently developed and used in various fields. The compound semiconductors are typically used for a light emitting element, such as a light emitting diode and a laser diode, and a solar cell using a photoelectric conversion effect, a thermoelectric conversion element using a Peltier effect, and the like.

A compound semiconductor solar cell uses a compound semiconductor in a light absorbing layer that absorbs solar light and generates electron-hole pairs. The light absorbing layer is formed using a III-V compound semiconductor such as GaAs, InP, GaAlAs and GaInAs, a II-VI compound semiconductor such as CdS, CdTe and ZnS, a compound semiconductor such as CuInSe₂.

Various layers formed of a compound semiconductor (hereinafter referred to as a compound semiconductor layer) may be formed by a metal organic chemical vapor deposition (MOCVD) method, a molecular beam epitaxy (MBE) method, or any other suitable method for forming an epitaxial layer and then a front electrode of a grid pattern is formed on the front surface of the compound semiconductor layer and a rear electrode of a sheet shape is formed on the rear surface of the compound semiconductor layer.

After the front electrode and the rear electrode are formed on the compound semiconductor layer, an etch stop layer is formed on a front surface of the compound semiconductor layer, mesa etching is performed using an etching solution (acid/alkaline) for etching a compound semiconductor forming a compound semiconductor layer, and then scribing the rear electrode exposed by mesa etching to form a plurality of compounds semiconductor solar cells.

Here, mesa etching refers to an etching process for manufacturing a plurality of compound semiconductor solar cells in one compound semiconductor layer by dividing one compound semiconductor layer into several layers.

In the method of manufacturing a compound semiconductor solar cell having such a configuration, the metal forming the rear electrode of the compound semiconductor solar cell has a low contact resistance with the lowermost layer of the compound semiconductor layer, for example, the rear contact layer formed of GaAs, it must not be etched through the mesa etching process and the epotaxial lift off (ELO) process, and it must satisfy other device demands such as high rear reflection.

Therefore, gold (Au) is usually used as the metal for forming the rear electrode.

However, since gold (Au) forming the rear electrode is very expensive, it is very difficult to lower the manufacturing cost of the compound semiconductor solar cell.

### SUMMARY OF THE INVENTION

There is a need for a novel method that can reduce the manufacturing cost by forming a rear electrode with a metal other than gold (Au) and ensure stability in a mesa etching process.

It is an object of the disclosure to provide a compound semiconductor solar cell capable of improving the yield in the mesa etching process and lowering the manufacturing cost, and a method of manufacturing the same.

In one aspect, a method for manufacturing a front electrode of a compound solar cell includes an electrode formation operation of forming a rear electrode including a first electrode layer directly contacting a rear surface of a compound semiconductor layer and a second electrode layer positioned on a rear surface of the first electrode layer and formed of a material different from the first electrode layer, and forming a plurality of front electrodes on a front surface of the compound semiconductor layer, an etch stop layer formation operation of forming a plurality of first etch stop layers covering the plurality of front electrodes, and forming a second etch stop layer covering the front edge portions and the side surfaces of the compound semiconductor layers, a mesa etching operation of etching a portion of the compound semiconductor layer not covered by the plurality of first etch stop layer from the front surface to the rear surface of the compound semiconductor layer, and a scribing operation of scribing the rear electrode at a portion where the compound semiconductor layer is removed by the mesa etching operation.

The mesa etching operation includes a first etching process using a first solution comprising hydrochloric acid (HCl), a second etching process using a second solution comprising ammonium hydroxide (NH₄OH), and a third etching process using a third solution comprising a different kind of component than the second solution.

The third solution is a mixed solution of phosphoric acid (H₃PO₄), hydrogen peroxide (H₂O₂), and de-ionized water (DI), more particularly the third solution is formed by mixing phosphoric acid:hydrogen peroxide:de-ionized water in a ratio of 1:0.3 to 3:5 to 20.

The third etching process is performed as the last process in the mesa etching operation and a lowermost layer of the compound semiconductor layer in direct contact with the first electrode layer is etched in the third etching process.

The lowermost layer of the compound semiconductor layer is formed of GaAs or AlGaAs.

The lowermost layer of the compound semiconductor layer is etched using the third etching process using the third solution, even if the first electrode layer is exposed to the third solution as soon as the lowermost layer is removed, The silver (Ag) forming the first electrode layer has etch resistance to the third solution, so that the first electrode layer can be prevented from being etched.

The first electrode layer is formed by depositing silver (Ag) to a thickness of 50 to 500 nm using physical vapor deposition, and the second electrode layer is formed by plating a metal material containing copper (Cu) to a thickness of 1 to 10 μm using an electroplating method.

The thickness of the second electrode layer is at least 70% of the thickness of the rear electrode.

The second etch stop layer is formed on a rear edge of the compound semiconductor layer.

The second etch stop layer is formed to a thickness of 5 to 500 μm and a width of the second etch stop layer in a portion covering a front edge portion of the compound semiconductor layer is in a range of 50 to 2,000 μm.

The first etch stop layer and the second etch stop layer are simultaneously formed of the same material in the etch stop layer formation operation.

The first etch stop layer and the second etch stop layer are formed with any one material selected from a polymer, epoxy, wax, resin, and photoresist, and have a viscosity of 50 to 1,000 cP at room temperature.

Alternatively, in the etch stop layer formation operation, the first etch stop layer and the second etch stop layer is formed of different materials.

The first etch stop layer is formed of any one material selected from a polymer, an epoxy, a wax, a resin, and a photoresist, and have a viscosity of 50 to 1,000 cP at room temperature, and the second etch stop layer is formed of another material selected from the polymer, the epoxy, the wax, the resin, and the photoresist except for the material forming the first stop layer, or an insulating tape.

As described above, when the mesa etching is performed after forming the second etch stop layer covering the side surface and the front edge portion of the compound semiconductor layer, and when the first etching process using the first solution is performed, since the rear electrode is not exposed to the first solution, the oxidation reaction of the layer formed of GaInP, AlInP, and AlGaInP among the various layers provided in the compound semiconductor layer is effectively performed.

Therefore, since the layer formed of GaInP, AlInP, and AlGaInP is effectively removed, mesa etching is normally performed.

In another aspect, a compound semiconductor solar cell includes a compound semiconductor layer, a rear electrode including a first electrode layer directly contacting a rear surface of the compound semiconductor layer and formed of silver (Ag), and a second electrode layer positioned on a rear surface of the first electrode layer and formed of copper (Cu), and a front electrode of a grid shape positioned on a front surface of the compound semiconductor layer.

The first electrode layer has a thickness of 50 to 500 nm, and the second electrode layer has a thickness of 1 to 10 μm and 70% or more of a thickness of the rear electrode.

According to the method for manufacturing a compound semiconductor solar cell according to the disclosure, it is unnecessary to use expensive metal such as gold (Au) when forming the rear electrode, so that the manufacturing cost of the compound semiconductor solar cell can be reduced.

Since the lowermost layer of the compound semiconductor layer is etched using the third etching process using silver (Ag) forming the first electrode layer and the third solution having the etch resistance property, when the lowermost layer is removed, it is possible to prevent the first electrode layer from being etched even when exposed to the third solution.

Since the mesa etching is performed after forming the second etch stop layer covering the side surface and the front edge portion of the compound semiconductor layer, the rear electrode is exposed to the first solution during the first etching process using the first solution so that the oxidation reaction of the layer formed of GaInP, AlInP, and AlGaInP among the various layers provided in the compound semiconductor layer can be effectively performed.

Therefore, since the layer formed of GaInP, AlInP, and AlGaInP is effectively removed, mesa etching is normally performed.

Thus, the stability in the mesa etching process can be ensured, the yield can be improved, and the manufacturing cost can be reduced.

### BRIEF DESCRIPTION OF THE DRAWINGS

FIG. 1 is a block diagram showing a method of manufacturing a compound semiconductor solar cell according to embodiments of the disclosure.

FIG. 2 is a process diagram showing the electrode formation operation shown in FIG. 1 according to embodiments of the disclosure.

FIG. 3 is a process diagram showing the first embodiment of the etch stop layer formation operation shown in FIG. 1.

FIG. 4 is a process diagram showing a second embodiment of the etch stop layer formation operation shown in FIG. 1.

FIG. 5 is a process diagram showing the mesa etching operation shown in FIG. 1 according to embodiments of the disclosure.

FIG. 6 is a process diagram showing the scribing operation shown in FIG. 1 according to embodiments of the disclosure.

FIG. 7 is a perspective view of a compound semiconductor solar cell manufactured by the manufacturing method shown in FIG. 1 according to embodiments of the disclosure.

FIG. 8 is a graph comparing the light reflectance of the rear electrode formation material by wavelength according to embodiments of the disclosure.

### DETAILED DESCRIPTION OF THE EMBODIMENTS

Reference will now be made in detail to implementations of the invention examples of which are illustrated in the accompanying drawings. Since the invention may be modified in various ways and may have various forms, specific implementations are illustrated in the drawings and are described in detail in the specification. However, it should be understood that the invention are not limited to specific disclosed implementations, but include all modifications, equivalents and substitutes included within the spirit and technical scope of the invention.

The terms ‘first’, ‘second’, etc., may be used to describe various components, but the components are not limited by such terms. The terms are used only for the purpose of distinguishing one component from other components.

For example, a first component may be designated as a second component without departing from the scope of the implementations of the invention. In the same manner, the second component may be designated as the first component.

The term “and/or” encompasses both combinations of the plurality of related items disclosed and any item from among the plurality of related items disclosed.

When an arbitrary component is described as “being connected to” or “being linked to” another component, this should be understood to mean that still another component(s) may exist between them, although the arbitrary component may be directly connected to, or linked to, the second component.

On the other hand, when an arbitrary component is described as “being directly connected to” or “being directly linked to” another component, this should be understood to mean that no other component exists between them.

The terms used in this application are used to describe only specific implementations or examples, and are not intended to limit the invention. A singular expression can include a plural expression as long as it does not have an apparently different meaning in context.

In this application, the terms “include” and “have” should be understood to be intended to designate that illustrated features, numbers, operations, operations, components, parts or combinations thereof exist and not to preclude the existence of one or more different features, numbers, operations, operations, components, parts or combinations thereof, or the possibility of the addition thereof.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present.

Unless otherwise specified, all of the terms which are used herein, including the technical or scientific terms, have the same meanings as those that are generally understood by a person having ordinary knowledge in the art to which the invention pertains.

The terms defined in a generally used dictionary must be understood to have meanings identical to those used in the context of a related art, and are not to be construed to have ideal or excessively formal meanings unless they are obviously specified in this application.

The following example implementations of the invention are provided to those skilled in the art in order to describe the invention more completely. Accordingly, shapes and sizes of elements shown in the drawings may be exaggerated for clarity.

Hereinafter, the present invention will be described with reference to the accompanying figures.

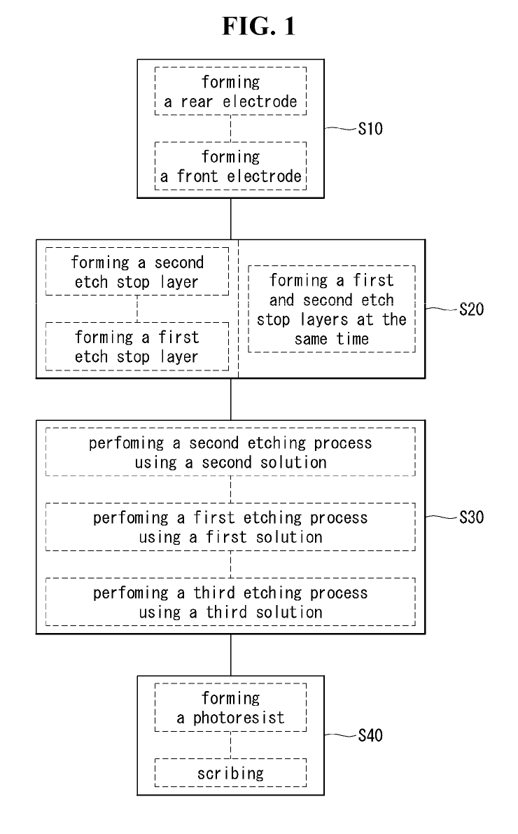

FIG. 1 is a block diagram showing a method of manufacturing a compound semiconductor solar cell according to embodiments of the disclosure and

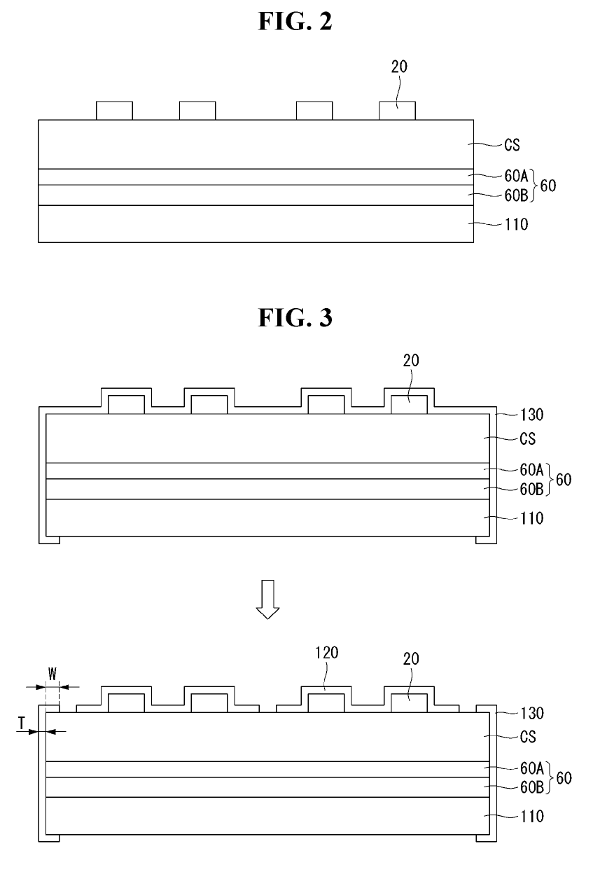

FIG. 2 is a process diagram showing the electrode formation operation shown in FIG. 1 according to embodiments of the disclosure.

FIG. 3 is a process diagram showing the first embodiment of the etch stop layer formation operation shown in FIG. 1 and

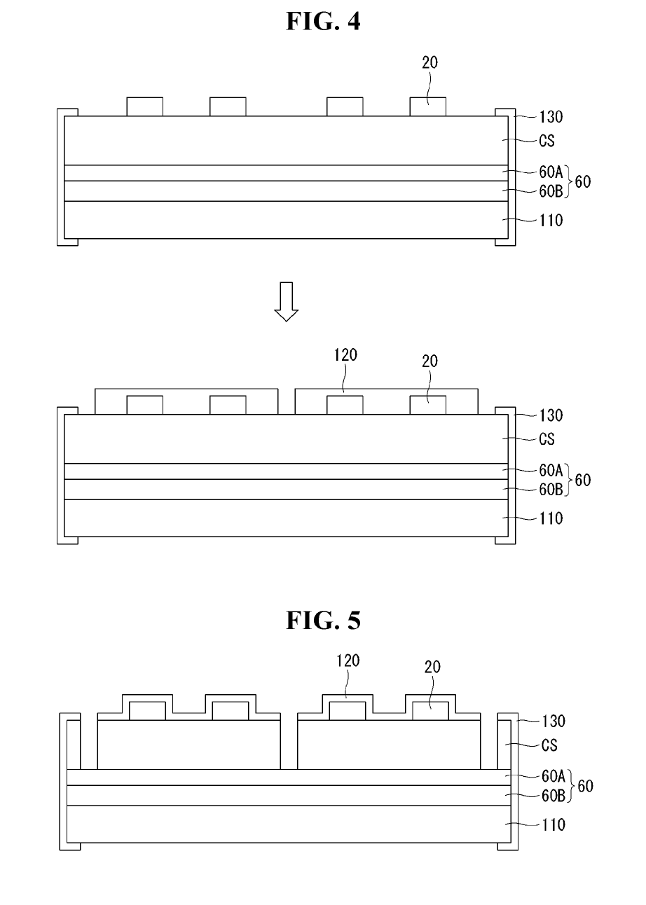

FIG. 4 is a process diagram showing a second embodiment of the etch stop layer formation operation shown in FIG. 1.

FIG. 5 is a process diagram showing the mesa etching operation shown in FIG. 1 according to embodiments of the disclosure,

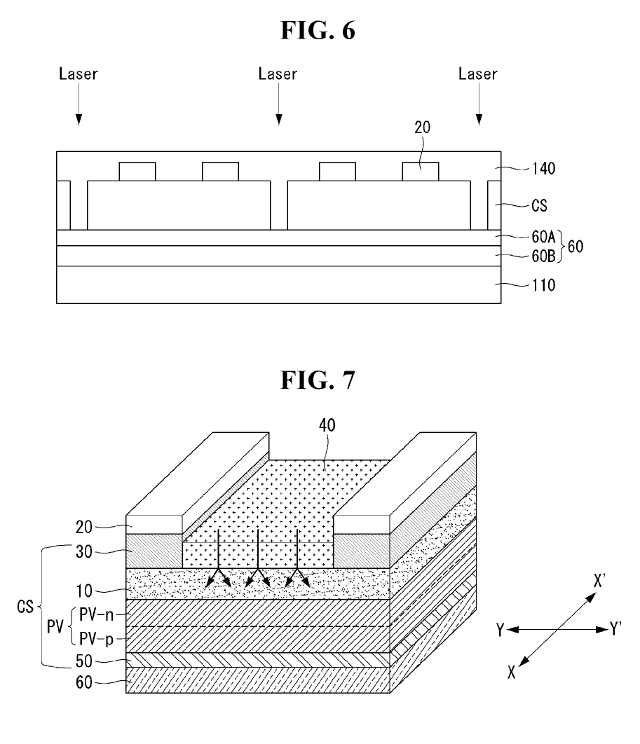

FIG. 6 is a process diagram showing the scribing operation shown in FIG. 1 according to embodiments of the disclosure and

FIG. 7 is a perspective view of a compound semiconductor solar cell manufactured by the manufacturing method shown in FIG. 1 according to embodiments of the disclosure.

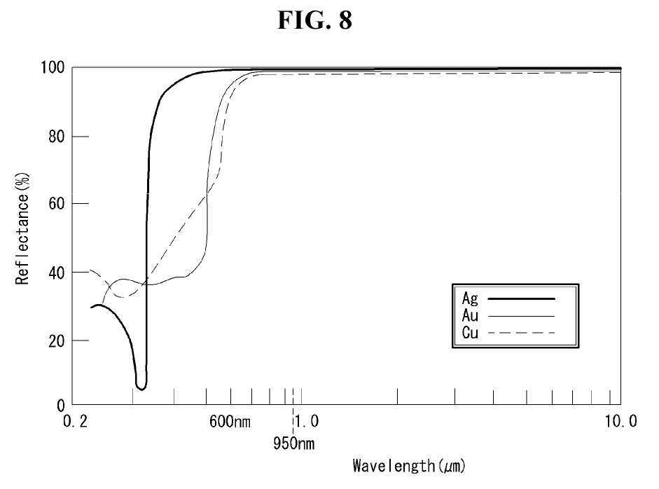

FIG. 8 is a graph comparing the light reflectance of the rear electrode formation material by wavelength according to embodiments of the disclosure.

Firstly, a compound semiconductor solar cell manufactured by the manufacturing method of the embodiment of the disclosure will be described with reference to FIG. 7.

A compound semiconductor solar cell of an implementation of the present invention may comprise a light absorbing layer PV, a window layer 10 positioned on a front surface of the light absorption layer, a front electrode 20 positioned on a front surface of the window layer 10, a first contact layer 30 positioned between the window layer 10 and the first electrode 20, an anti-reflection film 40 positioned on the window layer 10, a second contact layer 50 positioned on a rear surface of the light absorbing layer PV, and a rear electrode 60 positioned on a rear surface of the second contact layer 50.

In the instance, at least one of the anti-reflection film 40 and the window layer 10 may be omitted, but an instance where the anti-reflection film 40 and the window layer 10 are provided as shown in FIG. 7 will be described as an example.

The light absorbing layer PV may be formed to include a III-VI group semiconductor compound. For example, the light absorbing layer PV may be formed of an InGaP compound containing indium (In), gallium (Ga) and phosphide (P) or a GaAs compound containing gallium (Ga) and arsenic (As).

Hereinafter, a description will be given of an example in which the light absorption layer PV includes a GaAs compound.

The light absorbing layer PV may include a p-type semiconductor layer PV-p doped with an impurity of a first conductive type and an n-type semiconductor layer PV-n doped with an impurity of a second conductive type opposite the first conductive type.

The light absorbing layer PV may further include a back surface field layer.

The p-type semiconductor layer PV-p may be formed by doping a p-type impurity into the above-described compound, and the n-type semiconductor layer PV-n may be formed by doping an n-type impurity into the above-described compound.

Herein, the p-type impurity may be selected from carbon, magnesium, zinc or a combination thereof, and the n-type impurity may be selected from silicon, selenium, tellurium or a combination thereof.

The n-type semiconductor layer PV-n may be positioned in a region adjacent to the first electrode 120. The p-type semiconductor layer PV-p may be positioned in a region directly under the n-type semiconductor layer PV-n and may be positioned in a region adjacent to a second electrode (or a rear electrode) 60.

That is, the interval between the n-type semiconductor layer PV-n and the front electrode 20 is smaller than the interval between the p-type semiconductor layer PV-p and the front electrode 20. The interval between the n-type semiconductor layer (PV-n) and the rear electrode 60 is larger than the interval between the p-type semiconductor layer (PV-p) and the rear electrode 60.

As a result, a p-n junction in which the p-type semiconductor layer PV-p and the n-type semiconductor layer PV-n are joined is formed in the light absorbing layer PV. The electron-hole pairs generated by the light are separated into electrons and holes by the internal potential difference formed by the p-n junction of the light absorbing layer PV so that electrons move toward the n-type semiconductor layer PV-n and holes move toward the p-type semiconductor layer PV-p.

Therefore, the holes generated in the light absorbing layer PV move to the second electrode 60 through the second contact layer 50 and the electrons generated in the light absorbing layer PV moves to the first electrode 20 through the window layer 10 and the first contact layer 30.

Alternatively, the p-type semiconductor layer PV-p may be positioned in a region adjacent to the first electrode 20 and the n-type semiconductor layer PV-n may be positioned in a region directly under the p-type semiconductor layer PV-p and may be positioned in a region adjacent to the second electrode 60. In this instance, the holes generated in the light absorbing layer PV move to the first electrode 20 through the first contact layer 30 and the electrons generated in the light absorbing layer PV move to the second electrode 60 through the second contact layer 50.

In the instance where the light absorbing layer PV further includes the back surface field layer, the back surface field layer may have the same conductivity as the upper layer, that is, the n-type semiconductor layer PV-n or the p-type semiconductor layer PV-p and may be formed of the same material as the window layer 10.

In one example, the back surface field layer may be formed of AlGaInP.

In order to effectively block the movement of the charge (holes or electrons) to be moved toward the front electrode 20 toward the rear electrode 60, the back surface field layer is formed entirely on the rear surface of the upper layer directly contacting with the back surface field layer, that is, the n-type semiconductor layer PV-n or the p-type semiconductor layer PV-p.

That is, in the solar cell shown in FIG. 7, in the instance where the back surface field layer is formed on the rear surface of the p-type semiconductor layer PV-p, the back surface field layer functions to block the movement of electrons toward the rear electrode 60. In order to effectively block the movement of electrons toward the rear electrode 60, the back surface field layer is positioned on the entire rear surface of the p-type semiconductor layer PV-p.

The light absorbing layer PV having such a structure may be formed on a mother substrate by a metal organic chemical vapor deposition (MOCVD) method, a molecular beam epitaxy (MBE) method, or any other suitable method for forming an epitaxial layer.

In the instance of homogeneous junction, the p-type semiconductor layer PV-p and the n-type semiconductor layer PV-n may be made of the same material having the same band gap. Alternatively, in the instance of heterojunction, the p-type semiconductor layer PV-p and the n-type semiconductor layer PV-n may be made of different materials having different band gaps.

The window layer 10 may be formed between the light absorbing layer PV and the first electrode 20 and may be formed by doping an impurity of the second conductivity type into a III-VI group semiconductor compound.

Here, aluminum (Al) is included in the window layer 10 in order to form the energy band gap of the window layer 10 higher than the energy band gap of the light absorption layer.

However, when the p-type semiconductor layer PV-p is positioned on the n-type semiconductor layer PV-n and the window layer 10 is positioned on the p-type semiconductor layer PV-p, the window layer 10 may include a first conductivity type (i.e., a p-type) impurity.

However, the window layer 10 may not contain n-type or p-type impurities.

The window layer 10 serves to passivate the front surface of the light absorbing layer PV. Therefore, when the carrier (electrons or holes) moves to the surface of the light absorbing layer PV, the window layer 10 can prevent the carriers from recombining on the surface of the light absorbing layer PV.

Since the window layer 10 is disposed on the front surface (i.e., light incident surface) of the light absorbing layer PV, in order to prevent light incident on the light absorbing layer PV from being absorbed, the window layer 10 may have an energy band gap higher than the energy band gap of the light absorbing layer PV.

The anti-reflection film 40 may be located on the entire surface of the window layer 10 except the region where the first electrode 20 and/or the first contact layer 30 are located.

Alternatively, the anti-reflection film 40 may be disposed on the first contact layer 30 and the first electrode 20 as well as the exposed window layer 10.

In this instance, the compound semiconductor solar cell may further include at least one bus bar electrodes physically connecting the plurality of first electrodes 20, and the bus bar electrode may not be covered by the anti-reflection film 40 and can be exposed to the outside.

The anti-reflection film 40 having such a structure may include magnesium fluoride, zinc sulfide, titanium oxide, silicon oxide, derivatives thereof, or a combination thereof.

The front electrode 20 may be formed to extend in the first direction X-X′, and a plurality of the front electrodes 20 may be spaced apart from each other along a second direction Y-Y′ orthogonal to the first direction.

The front electrode 20 having such a configuration may be formed to include an electrically conductive material such as at least one of gold (Au), germanium (Ge), and nickel (Ni).

The first contact layer 30 positioned between the window layer 10 and the front electrode 20 is formed by doping the second impurity with a dopant concentration higher than the impurity doping concentration of the window layer 10 into the III-V compound semiconductor.

The front contact layer 30 forms an ohmic contact between the window layer 10 and the front electrode 20. That is, when the front electrode 20 directly contacts the window layer 10, the ohmic contact between the front electrode 20 and the light absorbing layer PV is not well formed because the impurity doping concentration of the window layer 10 is low. Therefore, the carrier moved to the window layer 10 cannot move to the front electrode 20 and can be destroyed or recombined.

However, when the front contact layer 30 is formed between the front electrode 20 and the window layer 10, since the front contact layer 30 forms an ohmic contact with the front electrode 20, the carrier is smoothly moved and the short circuit current density Jsc of the compound semiconductor solar cell increases. Thus, the efficiency of the solar cell can be further improved.

In order to form an ohmic contact with the front electrode 20, the doping concentration of the second dopant doped in the front contact layer 30 may be greater than the doping concentration of the second dopant doped in the window layer 10.

The front contact layer 30 is formed in the same shape as the first electrode 20.

A rear contact layer 50 disposed on the rear surface of the p-type semiconductor layer PV-p of the light absorbing layer PV is entirely located on the rear surface of the light absorbing layer PV and may be formed by doping the first conductive type impurity into the III-VI group semiconductor compound at a doping concentration higher than that of the p-type semiconductor layer PV-p.

The second contact layer 50 forms an ohmic contact with the rear electrode 60, so that the short circuit current density Jsc of the compound semiconductor solar cell can be further improved. Thus, the efficiency of the solar cell can be further improved.

The thickness of the front contact layer 30 and the thickness of the rear contact layer 50 may each be 100 nm to 300 nm. For example, the front contact layer 30 may be formed with a thickness of 100 nm and the rear contact layer 50 may be formed with a thickness of 300 nm.

The rear electrode 60 positioned on the rear surface of the rear contact layer 50 may be a sheet-like conductive layer positioned entirely on the rear surface of the light absorbing layer PV, different from the front electrode 20. That is, the rear electrode 60 may be referred to as a sheet electrode located on the entire rear surface of the light absorbing layer PV.

At this time, the rear electrode 60 may be formed in the same planar area as the light absorbing layer PV.

The first electrode layer 60A of the rear electrode 60 is located on the lowermost layer of the compound semiconductor layer CS, for example, the rear surface of the rear contact layer 50, and is in direct contact with the rear surface of the rear contact layer 50 to transmit a carrier. The second electrode layer 60B of the rear electrode 60 is disposed on the rear surface of the first electrode layer 60A to support the compound semiconductor layer CS during the manufacturing process of the compound semiconductor solar cell including the substrate separation process using the ELO (epitaxial lift off).

At this time, the first electrode layer 60A for transmitting a carrier is formed of a material having a contact resistance similar to that of a conventional rear electrode forming material with a high level of reflectivity and a contact resistance similar to gold (Au).

According to review of the contact resistance with the p+GaAs layer doped with zinc (Zn) at a high concentration of 1e19/cm³, gold (Au) has a contact resistance of about 3.5×10-3 Ωcm³, silver (Ag) has a contact resistance of about 3.6×10-3 Ωcm³ and copper (Cu) has a contact resistance of about 5.2×10-2 Ωcm³.

Further, referring to FIG. 8, according to review of the light reflectance of each wavelength, at a wavelength range of 600 nm to 950 nm, which is a wavelength range of interest, silver (Ag) has an average reflectivity of 95% or more, but copper (Cu) has a lower reflectivity than silver (Ag).

Therefore, the first electrode layer 60A directly contacting the rear contact layer 50 is formed of silver (Ag) having an excellent electrical bonding property with the rear contact layer 50 and having an average reflectivity of 95% or more at a wavelength range of 600 nm to 950 nm by physical vapor deposition (CVD) to a thickness of 50 to 500 nm.

The second electrode layer 60B is formed of copper (Cu) having a higher contact resistance than that of the silver (Ag) forming the first electrode layer 60B and a low reflectivity at a wavelength range of 600 nm to 950 nm, but having a low material cost by plating to a thickness of 1 to 10 μm.

As described, when silver (Ag) having a low contact resistance with the rear contact layer 50 and having a high average reflectivity in a wavelength range of 600 nm to 950 nm is used as the material for forming the first electrode layer 60A, the contact resistance with the rear contact layer 50 can be well maintained and the photon recycling can be increased due to the reduction in the optical loss, thereby improving the efficiency of the solar cell.

Hereinafter, a method of manufacturing a compound semiconductor solar cell will be described with reference to FIGS. 1 to 6.

The manufacturing method of the disclosure includes an electrode formation operation S10, an etch stop layer formation operation S20, a mesa etching operation S30, and a scribing operation S40.

Referring to FIG. 2, the electrode formation operation S10 includes forming electrodes on the back surface and the front surface of the compound semiconductor layer CS, respectively.

In the electrode formation operation S10, a sheet-shaped rear electrode 60 is formed. The rear electrode 60 includes a first electrode layer 60A directly contacting the rear surface of the compound semiconductor layer and a second electrode layer 60B located on the rear surface of the first electrode layer 60A at the rear surface of the compound semiconductor layer CS. Also, in the electrode formation operation S10, a plurality of front electrodes 20 provided on different compound semiconductor solar cells are formed on the front surface of the compound semiconductor layer CS.

The first electrode layer 60A may be formed by depositing silver (Ag) to a thickness of 50 to 500 nm by physical vapor deposition, and the second electrode layer 60B may be formed by depositing copper (Cu) to a thickness of 1 to 10 μm using electroplating.

The thickness of the second electrode layer 60B is preferably 70% or more of the thickness of the rear electrode 60.

The compound semiconductor layer CS may be formed by forming a sacrificial layer on one side of a mother substrate acting as a base for providing a suitable lattice structure in which the light absorbing layer PV is formed, and then various layers such as a rear contact layer, a back surface field layer, a p-type semiconductor layer, an n-type semiconductor layer, a window layer and an front contact layer are successively grown on a sacrificial layer, and then removing the layers to separate the various layers from the mother substrate by an ELO (epitaxial lift off).

Accordingly, the compound semiconductor layer CS may include the above-mentioned various layers, for example, a rear contact layer, a back surface field layer, a p-type semiconductor layer, an n-type semiconductor layer, a window layer, and an front contact layer.

The sacrificial layer and the compound semiconductor layer CS may be formed by a metal organic chemical vapor deposition (MOCVD) method, a molecular beam epitaxy (MBE) method, or any other suitable method for forming an epitaxial layer.

At this time, the mother substrate has a size capable of manufacturing a plurality of compound semiconductor solar cells, and the compound semiconductor layer (CS) formed on the sacrificial layer of the mother substrate has the same size as the mother substrate.

In order to simplify the figures, in FIG. 2 to FIG. 6, one compound semiconductor layer CS separated from the mother substrate forms two compound semiconductor solar cells. However, the number of compound semiconductor solar cells can be appropriately selected as needed or desired.

The front electrode 20 may be formed on the front surface of the compound semiconductor layer CS after the rear electrode 60 is formed and the carrier substrate 110 is attached to the rear surface of the rear electrode 60.

After the front electrode 20 and the rear electrode 60 are formed according to the above-described method, an etch stop layer formation operation S20 is performed.

The etch stop layer formation operation S20 includes forming the first etch stop layer 120 and the second etch stop layer 130.

The first etch stop layer 120 is a layer that covers a plurality of front electrodes 20 and is located at a portion where the plurality of front electrodes 20 are located in the front surface of the compound semiconductor layer CS. The second etch stop layer 130 is a layer covering the front edge portion and the side surface of the compound semiconductor layer CS.

The second etch stop layer 130 may further cover the rear edge portion of the compound semiconductor layer CS.

wherein the second etch stop layer 130 is formed to a thickness T of 5 to 500 μm and a width W of the second etch stop layer 130 in a portion covering a front edge portion of the compound semiconductor layer CS is in a range of 50 to 2,000 μm.

In the etch stop layer formation operation S20, the first etch stop layer 120 and the second etch stop layer 130 may be formed of the same material at the same time.

Regarding this, referring to FIG. 3, firstly, any one material selected from a polymer, an epoxy, a wax, a resin, and a photoresist having a viscosity of 50 to 1,000 cP at room temperature is coated on the front surface of the compound semiconductor layer CS.

Here, a spin coating method may be used for the coating of the material.

When the coating material is spin-coated on the front surface of the compound semiconductor layer CS, the coating material covers the side surface of the compound semiconductor layer CS or covers the rims of the side surface and the rear surface.

After the coating material is formed on the front surface and the side surface, or the front surface, the side surface and the rear surface of the compound semiconductor layer CS, if the remaining coating material is removed except for the regions where the first and second etch stop layers 120 and 130 are to be formed, the first and second etch stop layers 120 and 130 may be formed of the same material at the same time.

Here, forming the first and second etch stop layer 120 and 130 simultaneously means forming the first etch stop layer 120 and the second etch stop layer 130 by one operation.

Alternatively, the first and second etch stop layers 120 and 130 may be formed of different materials in the etch stop layer formation operation S20.

Regarding this, referring to FIG. 4, a material selected from the polymer, the epoxy, the wax, the resin, and the photoresist is spun onto the front surface of the compound semiconductor layer CS on the front surface and the side surface or the front surface, the side surface and the rear surface of the compound semiconductor layer CS. Next, by removing the remaining coating material except the portion where the second etch stop layer 130 is to be formed, or attaching the insulating tape to the side and front edge portions and the rear edge portion of the compound semiconductor layer CS, the etching stop layer 130 is firstly formed.

Thereafter, The first etch stop layer 120 is formed of another material selected from the polymer, the epoxy, the wax, the resin, and the photoresist except for the material forming the second stop layer 130.

After the first and second etch stop layer 120 and 130 are formed according to the above-described method, a mesa etching operation S30 is performed.

Referring to FIG. 5, the mesa etching refers to etching the portion of the compound semiconductor layer CS not covered by the plurality of first etch stop layer 120 from the front side to the rear side of the compound semiconductor layer CS and one compound semiconductor layer separated from the mother substrate is separated into a plurality of compound semiconductor layers to produce a plurality of compound semiconductor solar cells.

The mesa etching operation includes a first etching process using a first solution comprising hydrochloric acid (HCl), a second etching process using a second solution comprising ammonium hydroxide (NH₄OH), and a third etching process using a third solution comprising a different kind of component than the second solution.

Here, the first solution is used to remove the layers of GaInP, AlInP, and AlGaInP among the various layers included in the compound semiconductor layer CS, and the second solution is used to remove the layers of GaAs, AlGaAs among various layers included in the compound semiconductor layer CS.

The second solution can be formed by mixing ammonium hydroxide, hydrogen peroxide, and de-ionized water in a ratio of 1:2:10.

Typically, the lowermost layer (a rear contact layer 50) of the compound semiconductor solar cell CS in direct contact with the back electrode 60 is formed of GaAs or AlGaAs.

By removing the lowermost layer, for example, the rear contact layer 50 using the second solution, the first electrode layer 60A is exposed to the second solution at the moment of removing the rear contact layer 50 and the first electrode layer 60A formed of silver (Ag) is dissolved by the second solution.

Therefore, in the present invention, a third etching process using a third solution that can remove the rear contact layer 50 formed of GaAs or AlGaAs, while preventing the first electrode layer 60A from being dissolved is used to etch the lowermost layer (e.g., the rear contact layer) of the compound semiconductor layer.

As the third solution, a mixed solution of phosphoric acid (H₃PO₄)/hydrogen peroxide (H₂O₂)/de-ionized water (DI) having the corrosion resistance of silver which is the material of the first electrode layer can be used. The third solution is formed by mixing phosphoric acid:hydrogen peroxide:de-ionized water in a ratio of 1:0.3 to 3:5 to 20.

As described above, the third etching process using the third solution can be performed in the last operation (removing the lowest layer of the compound semiconductor layer in direct contact with the rear electrode) in the mesa etching operation.

When the lowermost layer of the compound semiconductor layer is etched using the third etching process using the third solution, even if the first electrode layer 60A is exposed to the third solution as soon as the lowermost layer is removed, The silver (Ag) forming the first electrode layer 60A has etch resistance to the third solution, so that the first electrode layer 60A can be prevented from being etched.

Typically, the front contact layer 30 and the rear contact layer 50 are formed of GaAs or AlGaAs and include a window layer 10 positioned between the front contact layer 30 and the rear contact layer 50, the light absorbing layer (PV) and the back surface field layer are formed of GaInP, AlInP, or AlGaInP.

Therefore, when the mesa etching operation is performed, the front contact layer 30 is removed by the second etching process using the second solution, and the first etching process using the first solution is performed to remove the window layer 10, the absorber layer (PV) and the back surface field layer, and then the rear contact layer 50 may be removed by a third etching process using the third solution.

On the other hand, the side surface and the front edge portion, or side surface, the front edge portion and the rear edge portion of the compound semiconductor layer (CS) are protected by the second etch stop layer 130 during performing the mesa etching operation.

Therefore, when the first etching process using the first solution is performed, the rear electrode 60 is not exposed to the first solution, so that the silver (Ag) forming the first electrode layer 60A and the copper (Cu) forming the second electrode layer 60B is prevented from being oxidized prior to the layers formed of GaInP, AlInP, and AlGaInP among the various layers provided in the compound semiconductor layer CS.

According to this, since the oxidation reaction of the layer formed of GaInP, AlInP, and AlGaInP is effectively performed among the various layers provided in the compound semiconductor layer CS, the layer formed of GaInP, AlInP, and AlGaInP is effectively removed. Therefore Mesa etching is normally performed.

The first and second etch stop layer 120 and 130 used in the mesa etching operation S30 are removed by an organic solvent after the mesa etching operation S30, or after the scribing operation, it can be removed together with the unnecessary portion of the compound semiconductor layer.

After the mesa etching operation S30 is performed, the scribing operation S40 is performed.

Referring to FIG. 6, a photoresist 140 covering the front surface of the compound semiconductor layer CS is firstly formed before the mesa etching operation, and then the compound semiconductor layer and the rear electrode 60 of the removed portion is scribed using a laser-cutting device to produce a plurality of compound semiconductor solar cells.

Meanwhile, the front contact layer 30 provided in the compound semiconductor solar cell may be removed by an etching process using the front electrode 20 as a mask after or before the scribing operation, as a result, the front contact layer 30 can be formed in the same pattern as the front electrode 20, as shown in FIG. 7.

The compound semiconductor solar cell manufactured according to the above-described method can be used for forming a rear electrode by using silver (Ag) and copper (Cu), which are much cheaper than gold (Au), and it is possible to effectively suppress a problem that occurs during the process, for example, a phenomenon in which a portion of the compound semiconductor layer is not etched and a phenomenon that a portion of the rear electrode is dissolved.

Table 1 below compares the electrical characteristics between a conventional compound semiconductor solar cell (having a rear electrode formed of gold (Au)) and examples 1 and 2 having a rear electrode including a first electrode layer 60A formed of silver (Ag) and a second electrode layer 60B formed of copper (Cu).

In the Table 1 below, the compound semiconductor solar cell of example 1 and the compound semiconductor solar cell of example 2 are two solar cells selected from a plurality of solar cells manufactured by the manufacturing method of the disclosure.

TABLE 1

| | Open-circuit | | |
|---|---|---|---|
| | voltage (Voc) | Fill Factor(FF) | Effective(Eff) |
| conventional | 2.528 | 82.1 | 21.6 |
| example 1 | 2.521 | 81.9 | 21.7 |
| example 2 | 2.535 | 81.9 | 21.6 |

Referring to Table 1, it can be seen that the compound semiconductor solar cells of examples 1 and 2 show the same or similar electrical characteristics as those of the conventional compound semiconductor solar cell.

Meanwhile, a metal protective layer may be formed to prevent the surface of the second electrode layer from being oxidized in the ELO process on the rear surface of the second electrode layer 60B, and formed of at least one selected from a material of any one of silver (Ag), gold (Au), platinum (Pt), palladium (Pd), nickel (Ni) and molybdenum (Mo) that have etch resistance to hydrofluoric acid (HF) used in the ELO process.

In the above description, the compound semiconductor solar cell includes one light absorbing layer as an example, but the light absorbing layer may be formed in plural.

In this instance, the lower light absorption layer may include a GaAs compound that absorbs light in a long wavelength band to perform photoelectric conversion, and the upper light absorption layer may include a GaInP compound that absorbs light in a short wavelength band to photoelectrically convert the light. A tunnel junction layer may be positioned between the upper light absorbing layer and the lower light absorbing layer.

Further, an intrinsic semiconductor layer may be formed between the p-type semiconductor layer and the n-type semiconductor layer of the light absorption layer.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for manufacturing a front electrode of a compound solar cell, the method comprising:
an electrode formation operation of forming a rear electrode including a first electrode layer directly contacting a rear surface of a compound semiconductor layer and a second electrode layer positioned on a rear surface of the first electrode layer and formed of a material different from the first electrode layer, and forming a plurality of front electrodes on a front surface of the compound semiconductor layer;
an etch stop layer formation operation of forming a plurality of first etch stop layers covering the plurality of front electrodes, and forming a second etch stop layer covering the front edge portions and the side surfaces of the compound semiconductor layers;
a mesa etching operation of etching a portion of the compound semiconductor layer not covered by the plurality of first etch stop layer from the front surface to the rear surface of the compound semiconductor layer; and
a scribing operation of scribing the rear electrode at a portion where the compound semiconductor layer is removed by the mesa etching operation.

2. The method of claim 1, wherein the mesa etching operation includes a first etching process using a first solution comprising hydrochloric acid (HCl), a second etching process using a second solution comprising ammonium hydroxide (NH₄OH), and a third etching process using a third solution comprising a different kind of component than the second solution.

3. The method of claim 2, wherein the third solution is a mixed solution of phosphoric acid (H₃PO₄), hydrogen peroxide (H₂O₂), and de-ionized water (DI).

4. The method of claim 3, wherein the third solution is formed by mixing phosphoric acid:hydrogen peroxide:de-ionized water in a ratio of 1:0.3 to 3:5 to 20.

5. The method of claim 3, wherein the third etching process is performed as the last process in the mesa etching operation, and
wherein a lowermost layer of the compound semiconductor layer in direct contact with the first electrode layer is etched in the third etching process.

6. The method of claim 5, wherein the lowermost layer of the compound semiconductor layer is formed of GaAs or AlGaAs.

7. The method of claim 1, wherein the first electrode layer is formed by depositing silver (Ag) to a thickness of 50 to 500 nm using physical vapor deposition.

8. The method of claim 7, wherein the second electrode layer is formed by plating a metal material containing copper (Cu) to a thickness of 1 to 10 μm using an electroplating method.

9. The method of claim 8, wherein the thickness of the second electrode layer is at least 70% of the thickness of the rear electrode.

10. The method of claim 7, wherein the second etch stop layer is formed on a rear edge of the compound semiconductor layer.

11. The method of claim 10, wherein the second etch stop layer is formed to a thickness of 5 to 500 μm and a width of the second etch stop layer in a portion covering a front edge portion of the compound semiconductor layer is in a range of 50 to 2,000 μm.

12. The method of claim 10, wherein the first etch stop layer and the second etch stop layer are simultaneously formed of the same material in the etch stop layer formation operation.

13. The method of claim 12, wherein the first etch stop layer and the second etch stop layer are formed with any one material selected from a polymer, epoxy, wax, resin, and photoresist, and have a viscosity of 50 to 1,000 cP at room temperature.

14. The method of claim 10, wherein the first etch stop layer and the second etch stop layer are formed of different materials in the etch stop layer formation operation.

15. The method of claim 14, wherein the first etch stop layer is formed of any one material selected from a polymer, an epoxy, a wax, a resin, and a photoresist, and have a viscosity of 50 to 1,000 cP at room temperature, and
wherein the second etch stop layer is formed of another material selected from the polymer, the epoxy, the wax, the resin, and the photoresist except for the material forming the first etch stop layer, or an insulating tape.

16. A compound semiconductor solar cell, comprising:
a compound semiconductor layer;
a rear electrode including a first electrode layer directly contacting a rear surface of the compound semiconductor layer and formed of silver (Ag), and a second electrode layer positioned on a rear surface of the first electrode layer and formed of copper (Cu); and
a front electrode of a grid shape positioned on a front surface of the compound semiconductor layer.

17. The compound semiconductor solar cell of claim 16, wherein the first electrode layer has a thickness of 50 to 500 nm.

18. The compound semiconductor solar cell of claim 17, wherein the second electrode layer has a thickness of 1 to 10 μm.

19. The compound semiconductor solar cell of claim 18, wherein the second electrode layer has a thickness of 70% or more of a thickness of the rear electrode.

20. A compound semiconductor solar cell, comprising:
a compound semiconductor layer;
a rear electrode lacking gold (Au), and having a first electrode layer directly contacting a rear surface of the compound semiconductor layer and a second electrode positioned on a rear surface of the first electrode layer; and
a front electrode of a grid shape positioned on a front surface of the compound semiconductor layer,
wherein the first electrode layer includes silver (Ag), and the second electrode layer includes copper (Cu).
